(19) United States
(12) Patent Application Publication
(10) Pub. No.: US 2025/0336756 A1
(43) Pub. Date: Oct. 30, 2025

(54) HYBRID COMBINATION OF THERMAL INTERFACE MATERIALS TO MITIGATE THERMAL GREASE PUMP-OUT

(71) Applicant: DELL PRODUCTS L.P., Round Rock, TX (US)

(72) Inventors: Travis C. North, Cedar Park, TX (US); Qinghong He, Austin, TX (US); Tzu Chau Chen, Wenshan District (TW); Pomin Shih, Beitou District (TW)

(21) Appl. No.: 18/645,867

(22) Filed: Apr. 25, 2024

(51) Int. Cl. H01L 23/373; H01L 23/42

(52) U.S. Cl. CPC H01L 23/373; H01L 23/42

(57) ABSTRACT

An information handling system includes a processor package having a processor die and a first thermal interface material that is deposited on a surface of the processor die. A second thermal interface material is deposited on the surface of the processor die around a periphery of the first thermal interface material and encloses the first thermal interface material.

### FIELD OF THE DISCLOSURE

The present disclosure generally relates to information handling systems, and more particularly relates to a hybrid combination of thermal interface materials to mitigate liquid metal great pump-out from a processor.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

An information handling system includes a processor package having a processor die and a first thermal interface material that is deposited on a surface of the processor die. A second thermal interface material is deposited on the surface of the processor die around a periphery of the first thermal interface material and encloses the first thermal interface material.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a block diagram of an information handling system according to an embodiment of the present disclosure;

FIGS. 2-3 are perspective views of a portion of a processor package, according to an embodiment of the present disclosure;

FIG. 4 is an exploded perspective view of a portion of a processor package, according to an embodiment of the present disclosure;

FIGS. 5-6 are perspective views of a portion of a processor package, according to an embodiment of the present disclosure;

FIG. 7 is a diagram of a processor block, according to an embodiment of the present disclosure;

FIG. 8 is a cross-sectional view of a processor block, according to an embodiment of the present disclosure; and

FIG. 9 is a flowchart of a method for assembling a portion of a processor package, according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

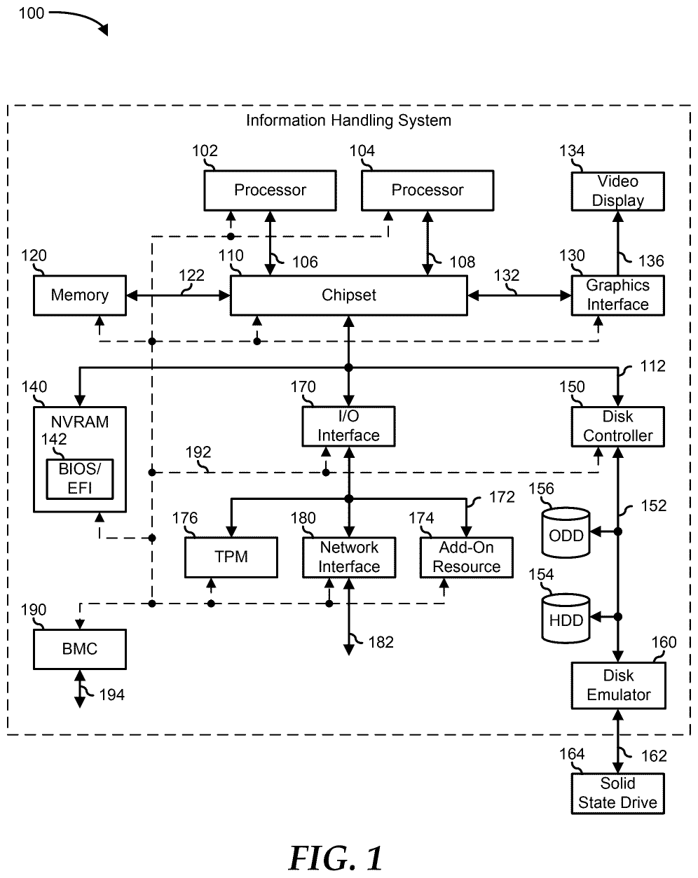

FIG. 1 illustrates an embodiment of an information handling system 100 including processors 102 and 104, a chipset 110, a memory 120, a graphics adapter 130 connected to a video display 134, a non-volatile RAM (NVRAM) 140 that includes a basic input and output system/extensible firmware interface (BIOS/EFI) module 142, a disk controller 150, a hard disk drive (HDD) 154, an optical disk drive 156, a disk emulator 160 connected to a solid-state drive (SSD) 164, an input/output (I/O) interface 170 connected to an add-on resource 174 and a trusted platform module (TPM) 176, a network interface 180, and a baseboard management controller (BMC) 190. Processor 102 is connected to chipset 110 via processor interface 106, and processor 104 is connected to the chipset via processor interface 108. In a particular embodiment, processors 102 and 104 are connected together via a high-capacity coherent fabric, such as a HyperTransport link, a QuickPath Interconnect, or the like. Chipset 110 represents an integrated circuit or group of integrated circuits that manage the data flow between processors 102 and 104 and the other elements of information handling system 100. In a particular embodiment, chipset 110 represents a pair of integrated circuits, such as a northbridge component and a southbridge component. In another embodiment, some or all of the functions and features of chipset 110 are integrated with one or more of processors 102 and 104.

Memory 120 is connected to chipset 110 via a memory interface 122. An example of memory interface 122 includes a Double Data Rate (DDR) memory channel and memory 120 represents one or more DDR Dual In-Line Memory Modules (DIMMs). In a particular embodiment, memory interface 122 represents two or more DDR channels. In another embodiment, one or more of processors 102 and 104 include a memory interface that provides a dedicated memory for the processors. A DDR channel and the connected DDR DIMMs can be in accordance with a particular DDR standard, such as a DDR3 standard, a DDR4 standard, a DDR5 standard, or the like.

Memory 120 may further represent various combinations of memory types, such as Dynamic Random Access Memory (DRAM) DIMMs, Static Random Access Memory (SRAM) DIMMs, non-volatile DIMMs (NV-DIMMs), storage class memory devices, Read-Only Memory (ROM) devices, or the like. Graphics adapter 130 is connected to chipset 110 via a graphics interface 132 and provides a video display output 136 to a video display 134. An example of a graphics interface 132 includes a Peripheral Component Interconnect-Express (PCIe) interface and graphics adapter 130 can include a four-lane (×4) PCIe adapter, an eight-lane (×8) PCIe adapter, a 16-lane (×16) PCIe adapter, or another configuration, as needed or desired. In a particular embodiment, graphics adapter 130 is provided down on a system printed circuit board (PCB). Video display output 136 can include a Digital Video Interface (DVI), a High-Definition Multimedia Interface (HDMI), a DisplayPort interface, or the like, and video display 134 can include a monitor, a smart television, an embedded display such as a laptop computer display, or the like.

NVRAM 140, disk controller 150, and I/O interface 170 are connected to chipset 110 via an I/O channel 112. An example of I/O channel 112 includes one or more point-to-point PCIe links between chipset 110 and each of NVRAM 140, disk controller 150, and I/O interface 170. Chipset 110 can also include one or more other I/O interfaces, including a PCIe interface, an Industry Standard Architecture (ISA) interface, a Small Computer Serial Interface (SCSI) interface, an Inter-Integrated Circuit (I²C) interface, a System Packet Interface, a Universal Serial Bus (USB), another interface, or a combination thereof. NVRAM 140 includes BIOS/EFI module 142 that stores machine-executable code (BIOS/EFI code) that operates to detect the resources of information handling system 100, to provide drivers for the resources, to initialize the resources, and to provide common access mechanisms for the resources. The functions and features of BIOS/EFI module 142 will be further described below.

Disk controller 150 includes a disk interface 152 that connects the disc controller to a hard disk drive (HDD) 154, to an optical disk drive (ODD) 156, and to disk emulator 160. An example of disk interface 152 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 160 permits SSD 164 to be connected to information handling system 100 via an external interface 162. An example of external interface 162 includes a USB interface, an institute of electrical and electronics engineers (IEEE) 1394 (Firewire) interface, a proprietary interface, or a combination thereof. Alternatively, SSD 164 can be disposed within information handling system 100.

I/O interface 170 includes a peripheral interface 172 that connects the I/O interface to add-on resource 174, to TPM 176, and to network interface 180. Peripheral interface 172 can be the same type of interface as I/O channel 112 or can be a different type of interface. As such, I/O interface 170 extends the capacity of I/O channel 112 when peripheral interface 172 and the I/O channel are of the same type, and the I/O interface translates information from a format suitable to the I/O channel to a format suitable to the peripheral interface 172 when they are of a different type. Add-on resource 174 can include a data storage system, an additional graphics interface, a network interface card (NIC), a sound/video processing card, another add-on resource, or a combination thereof. Add-on resource 174 can be on a main circuit board, on separate circuit board, or add-in card disposed within information handling system 100, a device that is external to the information handling system, or a combination thereof.

Network interface 180 represents a network communication device disposed within information handling system 100, on a main circuit board of the information handling system, integrated onto another component such as chipset 110, in another suitable location, or a combination thereof. Network interface 180 includes a network channel 182 that provides an interface to devices that are external to information handling system 100. In a particular embodiment, network channel 182 is of a different type than peripheral interface 172 and network interface 180 translates information from a format suitable to the peripheral channel to a format suitable to external devices.

In a particular embodiment, network interface 180 includes a NIC or host bus adapter (HBA), and an example of network channel 182 includes an InfiniBand channel, a Fibre Channel, a Gigabit Ethernet channel, a proprietary channel architecture, or a combination thereof. In another embodiment, network interface 180 includes a wireless communication interface, and network channel 182 includes a Wi-Fi channel, a near-field communication (NFC) channel, a Bluetooth® or Bluetooth-Low-Energy (BLE) channel, a cellular based interface such as a Global System for Mobile (GSM) interface, a Code-Division Multiple Access (CDMA) interface, a Universal Mobile Telecommunications System (UMTS) interface, a Long-Term Evolution (LTE) interface, or another cellular based interface, or a combination thereof. Network channel 182 can be connected to an external network resource (not illustrated). The network resource can include another information handling system, a data storage system, another network, a grid management system, another suitable resource, or a combination thereof.

BMC 190 is connected to multiple elements of information handling system 100 via one or more management interface 192 to provide out of band monitoring, maintenance, and control of the elements of the information handling system. As such, BMC 190 represents a processing device different from processor 102 and processor 104, which provides various management functions for information handling system 100. For example, BMC 190 may be responsible for power management, cooling management, and the like. The term BMC is often used in the context of server systems, while in a consumer-level device, a BMC may be referred to as an embedded controller (EC). A BMC included in a data storage system can be referred to as a storage enclosure processor. A BMC included at a chassis of a blade server can be referred to as a chassis management controller and embedded controllers included at the blades of the blade server can be referred to as blade management controllers. Capabilities and functions provided by BMC 190 can vary considerably based on the type of information handling system. BMC 190 can operate in accordance with an Intelligent Platform Management Interface (IPMI). Examples of BMC 190 include an Integrated Dell® Remote Access Controller (iDRAC).

Management interface 192 represents one or more out-of-band communication interfaces between BMC 190 and the elements of information handling system 100, and can include an Inter-Integrated Circuit (I2C) bus, a System Management Bus (SMBUS), a Power Management Bus (PMBUS), a Low Pin Count (LPC) interface, a serial bus such as a Universal Serial Bus (USB) or a Serial Peripheral Interface (SPI), a network interface such as an Ethernet interface, a high-speed serial data link such as a PCIe interface, a Network Controller Sideband Interface (NC-SI), or the like. As used herein, out-of-band access refers to operations performed apart from a BIOS/operating system execution environment on information handling system 100, that is apart from the execution of code by processors 102 and 104 and procedures that are implemented on the information handling system in response to the executed code.

BMC 190 operates to monitor and maintain system firmware, such as code stored in BIOS/EFI module 142, option ROMs for graphics adapter 130, disk controller 150, add-on resource 174, network interface 180, or other elements of information handling system 100, as needed or desired. In particular, BMC 190 includes a network interface 194 that can be connected to a remote management system to receive firmware updates, as needed or desired. Here, BMC 190 receives the firmware updates, stores the updates to a data storage device associated with the BMC, and transfers the firmware updates to an NVRAM of the device or system that is the subject of the firmware update, thereby replacing the currently operating firmware associated with the device or system, and reboots information handling system, whereupon the device or system utilizes the updated firmware image.

BMC 190 utilizes various protocols and application programming interfaces (APIs) to direct and control the processes for monitoring and maintaining the system firmware. An example of a protocol or API for monitoring and maintaining the system firmware includes a graphical user interface (GUI) associated with BMC 190, an interface defined by the Distributed Management Taskforce (DMTF) (such as a Web Services Management (WSMan) interface, a Management Component Transport Protocol (MCTP) or, a Redfish® interface), various vendor defined interfaces (such as a Dell EMC Remote Access Controller Administrator (RACADM) utility, a Dell EMC OpenManage Enterprise, a Dell EMC OpenManage Server Administrator (OMSA) utility, a Dell EMC OpenManage Storage Services (OMSS) utility, or a Dell EMC OpenManage Deployment Toolkit (DTK) suite), a BIOS setup utility such as invoked by a “F2” boot option, or another protocol or API, as needed or desired.

In a particular embodiment, BMC 190 is included on a main circuit board (such as a baseboard, a motherboard, or any combination thereof) of information handling system 100 or is integrated onto another element of the information handling system such as chipset 110, or another suitable element, as needed or desired. As such, BMC 190 can be part of an integrated circuit or a chipset within information handling system 100. An example of BMC 190 includes an iDRAC, or the like. BMC 190 may operate on a separate power plane from other resources in information handling system 100. Thus BMC 190 can communicate with the management system via network interface 194 while the resources of information handling system 100 are powered off. Here, information can be sent from the management system to BMC 190 and the information can be stored in a RAM or NVRAM associated with the BMC. Information stored in the RAM may be lost after power-down of the power plane for BMC 190, while information stored in the NVRAM may be saved through a power-down/power-up cycle of the power plane for the BMC.

Information handling system 100 can include additional components and additional busses, not shown for clarity. For example, information handling system 100 can include multiple processor cores, audio devices, and the like. While a particular arrangement of bus technologies and interconnections is illustrated for the purpose of example, one of skill will appreciate that the techniques disclosed herein are applicable to other system architectures. Information handling system 100 can include multiple central processing units (CPUs) and redundant bus controllers. One or more components can be integrated together. Information handling system 100 can include additional buses and bus protocols, for example, I2C and the like. Additional components of information handling system 100 can include one or more storage devices that can store machine-executable code, one or more communications ports for communicating with external devices, and various input and output (I/O) devices, such as a keyboard, a mouse, and a video display.

For purposes of this disclosure information handling system 100 can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 100 can be a personal computer, a laptop computer, a smartphone, a tablet device or other consumer electronic device, a network server, a network storage device, a switch, a router, or another network communication device, or any other suitable device and may vary in size, shape, performance, functionality, and price. Further, information handling system 100 can include processing resources for executing machine-executable code, such as processor 102, a programmable logic array (PLA), an embedded device such as a System-on-a-Chip (SoC), or other control logic hardware. Information handling system 100 can also include one or more computer-readable media for storing machine-executable code, such as software or data.

Information handling systems typically include thermal conducting components, such as processors, integrated heat spreaders, heat sinks, heat transfer dies, and a variety of other thermal conducting materials. As the heat production of the thermal conducting component increases, the transfer of heat between the thermal conducting components raises issues. A thermal interface material is typically used between thermal conducting components to fill air gaps in the thermal conduction path between two thermal conducting components.

However when pressure is applied to engage the thermal conducting components and heat is transferred between the thermal conducting components, the thermal interface typically thins and spreads across an interface surface between the thermal conducting components. This can cause the thermal interface material to gradually be squeezed out of the interface. This phenomenon may be referred to as “pump out” and is accelerated by the expansion and contraction of the thermal conducting components during heating and cooling cycles. In particular pump out occurs when there are temperature changes, the substrate and processor get warped at the microscopic level, and gradually move the thermal interface material outward. The pump-out process continues and eventually, there will be less thermal interface material which can lead to an increase in the temperature of the thermal conducting components. Accordingly, it would be desirable to prevent the thermal interface material from pumping out using a two-part interface material assembly or configuration provided by the present disclosure.

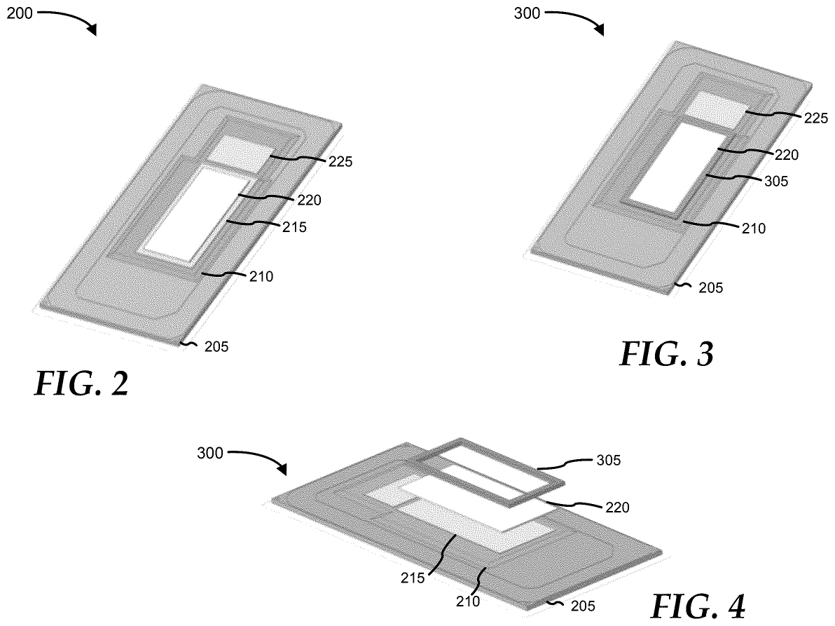

FIG. 2 shows a portion of a processor package 200 which may be housed inside an information handling system, such as information handling system 100 of FIG. 1. Processor package 200 can be a CPU package or a GPU package. Processor package 200 includes a package substrate 205, a stiffening structure 210, a processor die 215, a thermal interface material 220, and a processor die 225. Package substrate 205 may be configured as a base layer of processor package 200. Stiffening structure 210 may be configured to provide additional support.

Thermal interface material 220, can be a thermal grease, such as a liquid thermal grease or similar, and may be printed on or deposited on processor die 215. A surface area of processor die 215 covered by thermal interface material 220 may not extend over an entire surface area of processor die 215. Instead, thermal interface material 220 may be surrounded by a surface area of processor die 215 without thermal interface material 220. Thermal interface material 220 may also be referred to as an inner thermal interface material. Similarly, a thermal interface material may also be deposited on a surface area of processor die 225. In one example, thermal interface material 220 may have a thickness of 0.1 millimeters.

FIG. 3 shows a portion of a processor package 300 which can be processor package 200 with a thermal interface material 305 that may enclose the inner thermal interface material. Thermal interface material 305 may also be referred to as an outer thermal interface material. Further, thermal interface material 305 may be comprised of a thermal phase change material or similar. The thermal phase change material may be a traditional thermal interface pad or a dual phase change polymer solder hybrid. Thermal interface material 305 may be printed or deposited on a periphery of thermal interface material 220, such as the area of processor die 215 with no deposit of thermal interface material 220. Accordingly, thermal interface material 305 may surround or encircle thermal interface material 220.

Thermal interface material 305 may be used around thermal interface material 220 to form a barrier that can prevent thermal interface material 220 from pumping out. For example, thermal interface material 305 may adhere to a section of an area of a surface of processor die 215 sealing in thermal interface material 220. In particular, thermal interface material 305 may form a closed frame around thermal interface material 220 with a width and thickness that can keep thermal interface material 220 inside the closed frame and prevent thermal interface material 220 from migrating outside of its enclosed area. Thus, preventing thermal interface material 220 from pumping out of processor die 215.

In one example, the thickness of thermal interface material 305 may be greater than or equal to the thickness of thermal interface material 220 enclosing thermal interface material 220, such that thermal interface material 305 may be of the same level or higher than thermal interface material 220. As thermal interface material 220 thins and spreads across an interface surface of processor die 215, thermal interface material 220 may be stopped from pumping out of the interface surface area by thermal interface material 305. An extra barrier, such as a protection sponge and/or Mylar®, can be placed around processor package 300. Similarly, an outer thermal interface material may be deposited on processor die 225.

FIG. 4 shows an exploded view of various components of a portion of processor package 300. FIG. 4 is presented in view of FIG. 3 to facilitate a description of a process of assembling the portion of processor package 300. In this example, stiffening structure 210 may be placed on top of package substrate 205. Processor die 215 may be bonded to stiffening structure 210 while thermal interface material 220 may be deposited on processor die 215. Thermal interface material 305 may be printed or deposited on processor die 215 using a die-cut process enclosing thermal interface material 220.

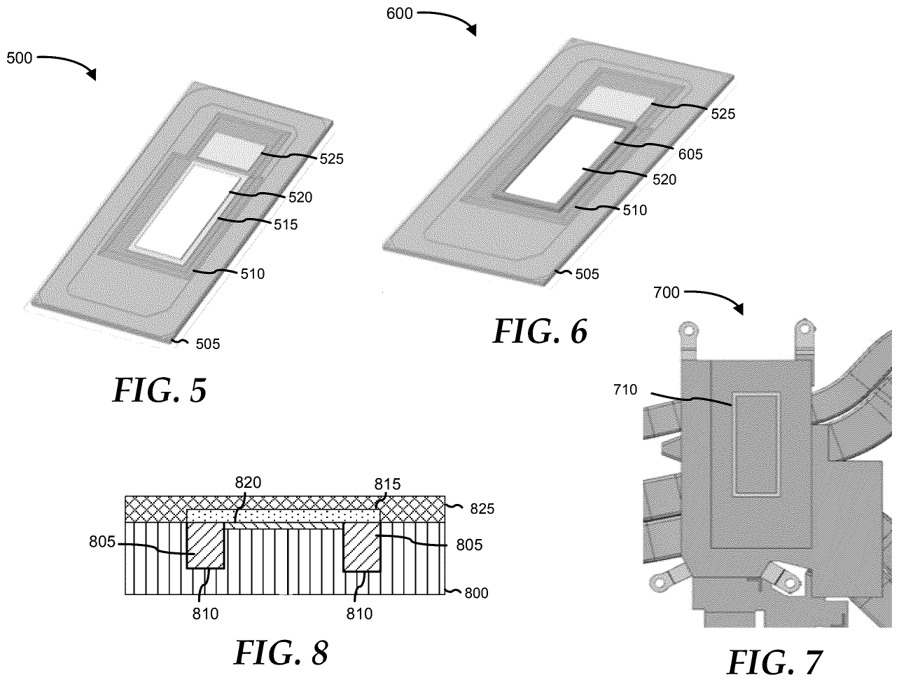

FIG. 5 shows a portion of a processor package 500 which may be housed inside an information handling system, such as information handling system 100 of FIG. 1. Processor package 500 may be similar to processor package 200 of FIG. 2. For example, processor package 500 can be a CPU package or a GPU package. Processor package 500 includes a package substrate 505, a stiffening structure 510, a processor die 515, a thermal interface material 520, and a processor die 525. Package substrate 505 may be similar to package substrate 205 while stiffening structure 510 may be similar to stiffening structure 210. In addition, processor die 515 may be similar to processor die 215 of FIG. 2 while processor die 525 may be similar to processor die 225 of FIG. 2.

Thermal interface material 520 is similar to thermal interface material 220 of FIG. 2. Accordingly, thermal interface material 520 can be a liquid thermal grease or similar material. Thermal interface material 520 may be printed or deposited on processor die 515. Thermal interface material 520 may not extend over an entire surface area of processor die 515. Instead, thermal interface material 520 may be surrounded by an area of processor die 515 without thermal interface material 520. In one example, thermal interface material 520 may have a thickness of 0.1 millimeters.

FIG. 6 shows a portion of a processor package 600 which can be processor package 500 that includes a thermal interface material 605. Thermal interface material 605 may be configured as an outer thermal interface material which may enclose an inner thermal interface material, such as thermal interface material 520. Thermal interface material 605 may be comprised of a liquid thermal gap filler or similar material. Thermal interface material 605 may be printed or deposited on the area of processor die 515 that surrounds thermal interface material 520, such as at a periphery of thermal interface material 520. Thermal interface material 605 may be used around thermal interface material 520 to form a barrier that can prevent thermal interface material 520 from pumping out. For example, thermal interface material 605 may adhere on a section of an area of a surface of processor die 515 sealing in thermal interface material 520. As thermal interface material 520 thins and spreads across an interface surface of processor die 515, thermal interface material 520 may be stopped from pumping out of the interface surface area by thermal interface material 605.

FIG. 7 shows a portion of processor block 700, also referred to as a CPU block may be a metal block that can be placed between a heat pipe and processor die 515 and/or thermal interface material 520 to transfer heat between the heat pipe and processor die 515. In one example, processor block 700 can be made with metal with properties that can transfer heat, such as copper. Processor block 700 may include a recessed portion, such as recess 710 that may be aligned with thermal interface material 605 to compensate for the thickness of thermal interface material 605. In this example, recess 710 may be configured to be aligned with a shape and dimension of thermal interface material 605 sealing in thermal interface material 520 within thermal interface material 605. Thus, preventing thermal interface material 520 from pumping out. For example, if thermal interface material 520 has a height of 0.1 millimeters, thermal interface material 605 may have a height or thickness that is greater than 0.1 millimeters, such as 0.25 millimeters.

FIG. 8 shows a cross-sectional view of a portion of a processor block 800 with a recess 810 in relation to a thermal interface material 805, thermal interface material 820, processor die 815, and stiffener structure 825. Processor block 800 may be similar to processor block 700 of FIG. 7 while recess 810 may be similar to recess 710 of FIG. 7. Thermal interface material 805 may be similar to thermal interface material 605 of FIG. 6 while thermal interface material 820 may be similar to thermal interface material 520 of FIG. 5. Processor die 815 may be similar to processor die 515 of FIG. 5 while stiffener structure 825 may be similar to stiffener structure 510. In this example, recess 810 is shown to compensate for the thickness of thermal interface material 805. For example, thermal interface material 805 may fill recess 810. Accordingly, the depth of recess 810 may be based on the thickness of thermal interface material 805. For example, if thermal interface material 805 has a height or thickness of 0.25 millimeters, then recess 810 may have a depth of around 0.25 millimeters.

Those of ordinary skill in the art will appreciate the configuration and components of a processor package and processor block depicted in FIGS. 2-8 may vary. For example, the illustrative components of the processor package and processor block are not intended to be exhaustive but rather are representative to highlight components that can be utilized to implement aspects of the present disclosure. For example, other thermal interface materials and/or thermal conducting components may be used in addition to or in place of the thermal interface materials and/or thermal conducting components depicted, respectively. The depicted example does not convey or imply any architectural or other limitations with respect to the presently described embodiments and/or the general disclosure. In the discussion of the figures, reference may also be made to components illustrated in other figures for continuity of the description.

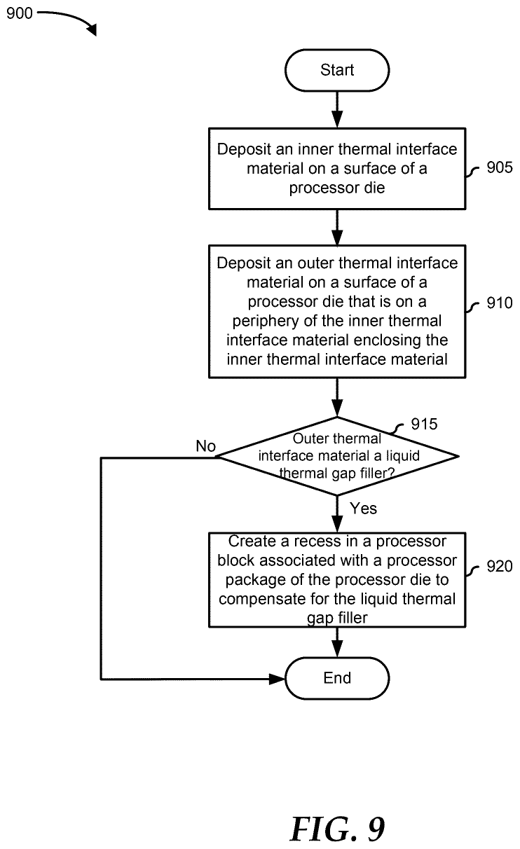

FIG. 9 shows a flowchart of a method 900 for a hybrid combination of thermal interface materials to mitigate liquid metal grease pump-out from a processor. The hybrid combination of thermal interface materials includes an inner thermal interface material and an outer thermal interface material that encloses and holds the inner thermal interface material in place preventing the inner thermal interface material from being pumped out. Method 900 may be performed as part of a manufacturing process of a processor package and/or an information handling system, such as processor package 200 of FIG. 2 and information handling system 100 of FIG. 1, respectively. While embodiments of the present disclosure are described in terms of the components of processor package and processor block of FIGS. 2-8, it should be recognized that other components may be utilized. One of skill in the art will appreciate that this sequence diagram explains a typical example, which can be extended in practice.

Method 900 typically starts at block 905 where an inner thermal interface material, such as a liquid thermal grease may be deposited on a surface area of a processor die wherein the liquid thermal grease may be bounded by an area of the processor die without the inner thermal interface material. The inner thermal interface material may occupy a first area of the surface of the processor die which is less than the surface of the processor die.

The method proceeds to block 910 wherein an outer thermal interface material may be printed or deposited on the area of the processor die around the periphery of the inner thermal interface material, enclosing the inner thermal interface. The outer thermal interface material may be in contact with the surface of the processor die sealing in the first thermal interface material. For example, a die-cut process may be used to remove a central portion of the outer thermal interface material, such that the outer thermal interface may have a hollow center prior to depositing or printing the outer thermal interface on the processor die.

The removed central portion may be based on the area occupied by the inner thermal interface on the surface of the processor die. For example, an area of the removed central portion may be similar to the area of the inner thermal interface material, or the surface area of the processor die occupied by the inner thermal interface. In addition, the removed central portion of the outer thermal interface material may have similar dimensions as the inner thermal interface. Similarly, a perimeter of the outer thermal interface material may be similar to a perimeter of the processor die. Thus, the area occupied by the first thermal interface material and the area occupied by the second thermal interface material may be equal to the surface area of the processor die.

The method proceeds to decision block 915 where the method may determine whether the outer thermal interface material is a liquid thermal gap filler. If the outer thermal interface material is a liquid thermal gap filler, then the “YES” branch is taken, and the method proceeds to block 920. If the outer thermal interface material is not a liquid thermal gap filler, then the “NO” branch is taken, and the method ends. At block 920, the method may create a recess in a processor block to compensate for the thickness of the liquid thermal gap filler.

As used herein, the terms “top” and “bottom” are provided in relation to the current figures, and in a typical information handling system the processor package may be arranged on a different surface than illustrated herein. In addition, although FIG. 9 shows example blocks of method 900 in some implementations, method 900 may include additional blocks, fewer blocks, different blocks, or differently arranged blocks than those depicted in FIG. 9. Those skilled in the art will understand that the principles presented herein may be implemented in any suitably arranged processing system. Additionally, or alternatively, two or more of the blocks of method 900 may be performed in parallel. For example, blocks 905 and 910 of method 900 may be performed in parallel.

In accordance with various embodiments of the present disclosure, the methods described herein may be implemented by software programs executable by a computer system. Further, in an exemplary, non-limited embodiment, implementations can include distributed processing, component/object distributed processing, and parallel processing. Alternatively, virtual computer system processing can be constructed to implement one or more of the methods or functionalities as described herein.

When referred to as a “device,” a “module,” a “unit,” a “controller,” or the like, the embodiments described herein can be configured as hardware. For example, a portion of an information handling system device may be hardware such as, for example, an integrated circuit (such as an Application Specific Integrated Circuit (ASIC), a Field Programmable Gate Array (FPGA), a structured ASIC, or a device embedded on a larger chip), a card (such as a Peripheral Component Interface (PCI) card, a PCI-express card, a Personal Computer Memory Card International Association (PCMCIA) card, or other such expansion card), or a system (such as a motherboard, a system-on-a-chip (SoC), or a stand-alone device).

The present disclosure contemplates a computer-readable medium that includes instructions or receives and executes instructions responsive to a propagated signal; so that a device connected to a network can communicate voice, video, or data over the network. Further, the instructions may be transmitted or received over the network via the network interface device.

While the computer-readable medium is shown to be a single medium, the term “computer-readable medium” includes a single medium or multiple media, such as a centralized or distributed database, and/or associated caches and servers that store one or more sets of instructions. The term “computer-readable medium” shall also include any medium that is capable of storing, encoding or carrying a set of instructions for execution by a processor or that cause a computer system to perform any one or more of the methods or operations disclosed herein.

In a particular non-limiting, exemplary embodiment, the computer-readable medium can include a solid-state memory such as a memory card or other package that houses one or more non-volatile read-only memories. Further, the computer-readable medium can be a random-access memory or other volatile re-writable memory. Additionally, the computer-readable medium can include a magneto-optical or optical medium, such as a disk or tapes, or another storage device to store information received via carrier wave signals such as a signal communicated over a transmission medium. A digital file attachment to an e-mail or other self-contained information archive or set of archives may be considered a distribution medium that is equivalent to a tangible storage medium. Accordingly, the disclosure is considered to include any one or more of a computer-readable medium or a distribution medium and other equivalents and successor media, in which data or instructions may be stored.

Although only a few exemplary embodiments have been described in detail above, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents but also equivalent structures.

What is claimed is:

1. An information handling system comprising:
a processor package including:
a processor die;
a first thermal interface material that is deposited on a surface of the processor die; and
a second thermal interface material that is deposited on the surface of the processor die around a periphery of the first thermal interface material and encloses the first thermal interface material.

2. The information handling system of claim 1, wherein the first thermal interface material is a liquid thermal grease.

3. The information handling system of claim 1, wherein the second thermal interface material is a phase change material.

4. The information handling system of claim 1, wherein the second thermal interface material is a liquid thermal gap filler.

5. The information handling system of claim 4, wherein a processor block associated with the processor package with the liquid thermal gap filler includes a recess to compensate for thickness of the liquid thermal gap filler.

6. The information handling system of claim 1, wherein the first thermal interface material occupies a first area of the surface of the processor die that is less than the surface of the processor die.

7. The information handling system of claim 1, wherein the second thermal interface material is in contact with the surface of the processor die sealing in the first thermal interface material.

8. A processor package comprising:
a processor die;
a first thermal interface material that is deposited on a surface of the processor die; and
a second thermal interface material that is deposited around a periphery of the first thermal interface material on the surface of the processor die and enclosing the first thermal interface material.

9. The processor package of claim 8, wherein the first thermal interface material is a liquid thermal grease.

10. The processor package of claim 8, wherein the second thermal interface material is a phase change material.

11. The processor package of claim 8, wherein the second thermal interface material is a liquid thermal gap filler.

12. The processor package of claim 11, wherein a processor block associated with the processor package includes a recess to compensate for thickness of the liquid thermal gap filler.

13. The processor package of claim 8, wherein the first thermal interface material occupies a first area of the surface of the processor die which is less than the surface of the processor die.

14. A method comprising:
depositing a first thermal interface material on a surface of a processor die; and
enclosing the first thermal interface material on the surface of the processor die by depositing a second thermal interface material around a periphery of the first thermal interface material.

15. The method of claim 14, wherein the first thermal interface material is a liquid thermal grease.

16. The method of claim 14, wherein the second thermal interface material is a phase change material.

17. The method of claim 14, wherein the second thermal interface material is a liquid thermal gap filler.

18. The method of claim 17, further comprising creating a recess on a processor block to compensate for thickness of the liquid thermal gap filler.

19. The method of claim 18, wherein the second thermal interface material fills the recess of the processor block.

20. The method of claim 18, wherein the first thermal interface material occupies a first area of the surface of the processor die which is less than the surface of the processor die.
